(19) United States
(12) Patent Application Publication
(10) Pub. No.: US 2018/0350630 A1
(43) Pub. Date: Dec. 6, 2018

(54) SYMMETRIC EMBEDDED TRACE SUBSTRATE

(71) Applicant: QUALCOMM Incorporated, San Diego, CA (US)

(72) Inventors: Kuiwon KANG, San Diego, CA (US); Marcus HSU, San Diego, CA (US); Hong Bok WE, San Diego, CA (US)

(21) Appl. No.: 15/814,355

(22) Filed: Nov. 15, 2017

Related U.S. Application Data
(60) Provisional application No. 62/513,985, filed on Jun. 1, 2017.

(51) Int. Cl. H01L 21/56; H01L 23/31; H01L 23/498; H01L 23/532; H01L 23/00; H01L 23/13

(52) U.S. Cl. CPC H01L 21/563; H01L 23/3114; H01L 23/49816; H01L 2224/16; H01L 24/33; H01L 23/13; H01L 23/532

(57) ABSTRACT

Exemplary packages according to some aspects of the disclosure may include a symmetric structure with a thick core for embedded trace substrates. The packages may include an embedded third dielectric layer for preventing bump shorts or trace peel off between fine bump areas with a solder resist trench. This may allow fine bump pitches with escape lines (traces) on flip chip bump array (FCBGA) applications, for example.

### CROSS-REFERENCE TO RELATED APPLICATIONS

The present Application for Patent claims the benefit of U.S. Provisional Application No. 62/513,985, entitled “SYMMETRIC EMBEDDED TRACE SUBSTRATE”, filed Jun. 1, 2017, assigned to the assignee hereof, and expressly incorporated herein by reference in its entirety.

### FIELD OF DISCLOSURE

This disclosure relates generally to substrates, and more specifically, but not exclusively, to substrates with embedded traces.

### BACKGROUND

Current Flip Chip Ball Grid Array (FCBGA) substrates use a thick core, thicker than other semiconductor substrates such as for wire bond, chip scale packages, or similar semiconductor packages, and have a limited fine bump pitch due to the trace pattern exposed on the surface of the substrate. The exposed trace pattern is subject to bump bridge shorts (shorts between the trace and adjoining pad caused by the solder ball connecting the flip chip to the pad on the substrate) and trace peel off risks (the risk of a thin copper trace peeling off of the surface of the substrate). Also conventional embedded trace substrates (ETS) cannot be used for FCBGA applications due to the very thick core needed in FCBGA substrates. Since there is a continuous drive in the industry for finer bump pitches (such as a 90 um pitch with two escape lines/traces) and current approaches have obvious bump shorts and high trace peel off risks, there is a need for systems, apparatus, and methods that overcome the deficiencies of conventional approaches including the methods, system and apparatus provided hereby.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

In one aspect, a package comprises: a substrate comprising a core, a first dielectric layer on a first side of the core, a second dielectric layer on a second side of the core opposite the first dielectric layer, and a third dielectric layer on the first dielectric layer; a plurality of pads embedded in the third dielectric layer such that a surface of each of the plurality of pads is below a surface of the third dielectric layer, the plurality of pads configured to connect to a flip chip semiconductor die and extend through the third dielectric layer; a plurality of traces embedded in the third dielectric layer such that a surface of each of the plurality of traces is below the surface of the third dielectric layer and extends through the third dielectric layer, at least two of the plurality of traces between each pair of adjoining pads of the plurality of pads; a first via proximate to a first edge of the substrate; and a second via proximate to a second edge of the substrate opposite the first edge.

In another aspect, a package comprises: a substrate comprising a core, a first dielectric layer on a first side of the core, a second dielectric layer on a second side of the core opposite the first dielectric layer, and means for insulation on the first dielectric layer; means for connection embedded in the means for insulation such that a surface of each of the means for connection is below a surface of the means for insulation, the means for connection configured to connect to a flip chip semiconductor die and extend through the means for insulation; means for routing embedded in the means for insulation such that a surface of each of the means for routing is below the surface of the means for insulation and extends through the means for insulation, at least two of the means for routing between each pair of adjoining means for connection; a first via proximate to a first edge of the substrate; and a second via proximate to a second edge of the substrate opposite the first edge.

In still another aspect, a method for forming a package substrate comprises: forming a core; forming a first dielectric layer on the core; forming a second dielectric layer on the core opposite the first dielectric layer; forming a plurality of pads on the first dielectric layer opposite the core; forming a plurality of traces on the first dielectric layer between the plurality of pads; forming a third dielectric layer on the first dielectric layer, the third dielectric layer configured to encapsulate the plurality of pads and the plurality of traces; forming a first via proximate to a first edge of the core; forming a second via proximate to a second edge of the core opposite the first edge of the core; removing a surface of the third dielectric layer such that the plurality of pads and the plurality of traces are exposed; forming a fourth layer on a portion of the third dielectric layer such that the plurality of pads and the plurality of traces are exposed; and removing a portion of each of the plurality of pads and each of the plurality of traces such that a surface of each of the plurality of pads and each of the plurality of traces is recessed from the surface of the third dielectric layer.

Other features and advantages associated with the apparatus and methods disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an exemplary substrate with flip chip and two escape lines in accordance with some examples of the disclosure.

FIGS. 2A-E illustrate an exemplary partial method for manufacture of a substrate with flip chip and two or multiple escape lines in accordance with some examples of the disclosure.

FIG. 3 illustrates an exemplary partial method for forming a flip chip bump array (FCBGA) package in accordance with some examples of the disclosure.

FIG. 4 illustrates various electronic devices that may be integrated with any of the aforementioned integrated device, semiconductor device, integrated circuit, die, interposer, package or package-on-package (PoP) in accordance with some examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

The exemplary methods, apparatus, and systems disclosed herein mitigate shortcomings of the conventional methods, apparatus, and systems, as well as other previously unidentified needs.

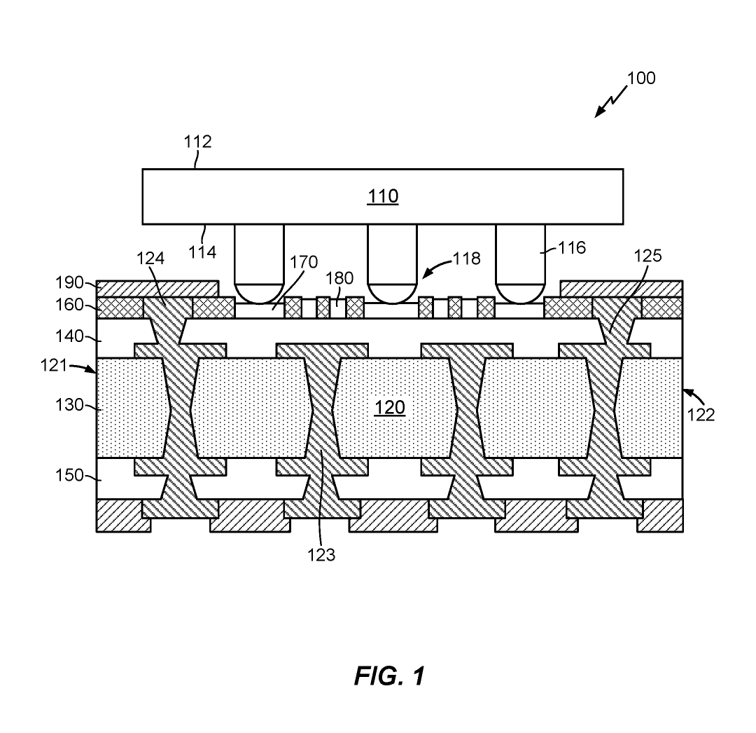

FIG. 1 illustrates an exemplary substrate with flip chip and two escape lines in accordance with some examples of the disclosure. As shown in FIG. 1, a package 100 may include a semiconductor die 110 (e.g., a flip chip logic die) and a substrate 120. The semiconductor die 110 may include a back side 112 facing away from the substrate 120, an active side 114 facing towards the substrate 120, and a bump array 116 on the active side 114. The bump array 116 may comprise a plurality of solder balls or Cu pillar with or without solder caps 118 configured to connect the semiconductor die 110 to the substrate 120. The substrate 120 may include a first edge 121 and a second edge 122 opposite the first edge 121.

The substrate 120 may comprise a core 130, a first dielectric layer 140 on a first side of the core 130, a second dielectric layer 150 on a second side of the core 130 opposite the first dielectric layer 140, a third dielectric layer 160 on the first dielectric layer 140, and a fourth layer 190 on a portion of the third dielectric layer 160 such that a plurality of pads 170 and a plurality of traces 180 are exposed and on the second dielectric layer 150 such that portions of a plurality of vias 123 are exposed. The plurality of vias 123 may include a first via 124 proximate to the first edge 121 of the substrate 120 and a second via 125 proximate to the second edge 122 of the substrate 120. The substrate 120 may also include a plurality of pads 170 embedded in the third dielectric layer 160 such that a surface of each of the plurality of pads 170 is recessed below a surface of the third dielectric layer 160 and the plurality of pads 170 are configured to connect to the semiconductor die 110 through the bump array 116 as well as extend entirely through the third dielectric layer 160. The substrate 120 may also include a plurality of traces 180 embedded in the third dielectric layer 160 extending entirely through the third dielectric layer 160 between the plurality of pads 170 such that a surface of each of the plurality of traces 180 is recessed below the surface of the third dielectric layer 160 and two of the plurality of traces 180 are between adjoining ones of the plurality of pads 170 and are configured to route signals from the plurality of pads 170 to other points or connections on and off the substrate 120. The substrate 120 may also include a plurality of vias 123 that extend from the third dielectric layer 160 to the second dielectric layer 150 to allow signals to be routed from a top of the substrate 120 to a bottom of the substrate 120.

The total thickness of package 100 depends on the layer count of substrate 120 and the thickness of semiconductor die 110. As shown the substrate 120 includes four layers but it should be understood that more or less layers may be used, such as 4-12 layers. Unlike conventional embedded trace substrates, the substrate 120 has a core 130 at the center and asymmetric structure about the core 130. The core 130 may comprise one of an organic, a silicon, a silicon dioxide, an aluminum oxide, a sapphire, a germanium, a gallium arsenide, an alloy of silicon and germanium, an indium phosphide, or similar material. The first dielectric layer 140 and the second dielectric layer 150 may be comprised of an ajinomoto-buildup film, for example, or other suitable material. The third dielectric layer 160 may be composed of one of ajinomoto-buildup film, prepreg insulation, resin coated copper, photo-sensitive resistor material, or similar material. The fourth layer 190 may be composed of a photo solder resist material. The thickness of the third dielectric layer 160 may be between 10 to 20 μm with a target of 15 μm. The dimensions of each of the plurality of traces 180 may be between 3 μm/3 μm to 15 μm/15 μm and each of the plurality of pads 170 may be between 16 μm to 40 μm in width. The thickness of the fourth layer 190 may be 15+/−5 μm for both the top and bottom. Each of the plurality of pads 170 and each of the plurality of traces 180 may have a recessed depth of approximately 0 to 4 μm (flat depth) below the surface of the third dielectric layer 160. A distance between one of the plurality of pads 170 and an adjoining one of the plurality of traces 180 may be between approximately 5 to 15 μm. As shown in FIG. 1, two of the plurality of traces 180 are between each adjoining ones of the plurality of pads 170, but it should be understood that more or less traces may be between adjoining pads. The recessed plurality of pads 170 and the plurality of traces 180 allow the plurality of solder balls 118 to connect with a respective one the plurality of pads 170 with shorting the connection to an adjoining one of the plurality of traces 180 and prevent or lessen the risk of the plurality of traces 180 peeling off of the substrate 120.

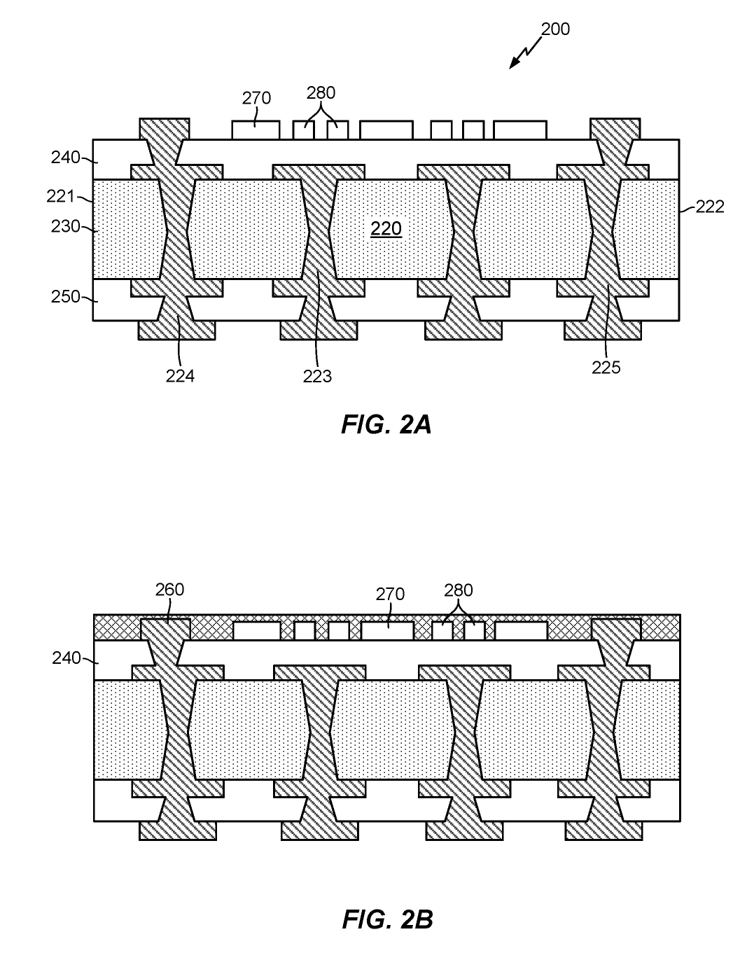

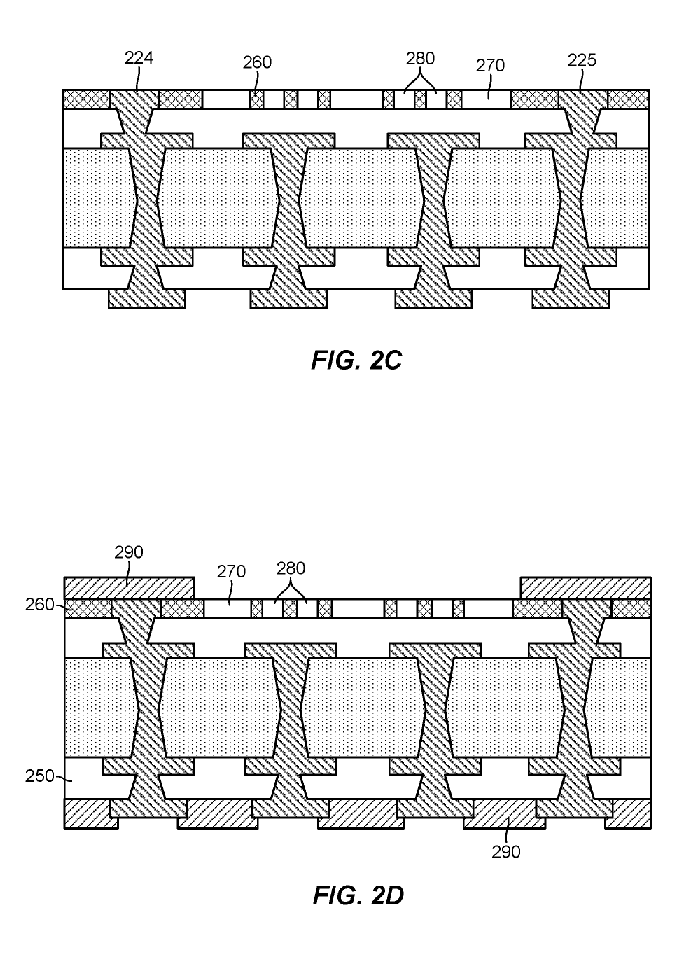

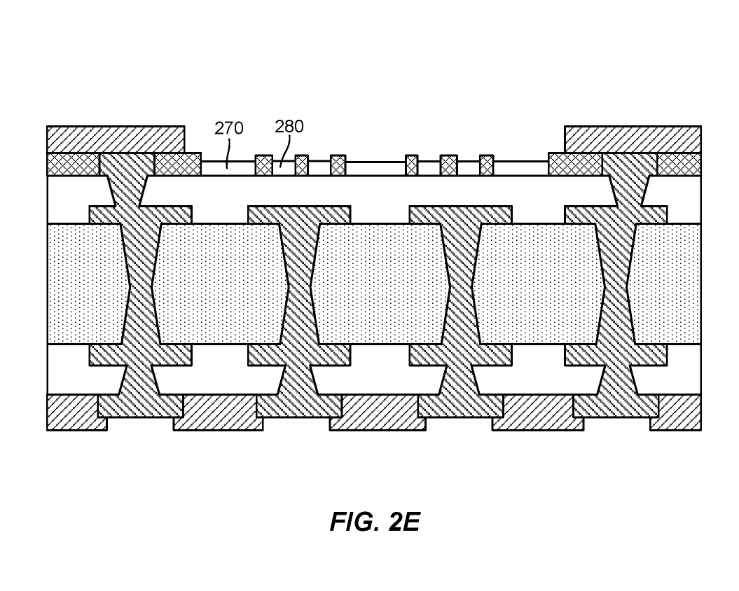

FIGS. 2A-E illustrate an exemplary partial method for manufacture of a substrate with flip chip and two or multiple escape lines in accordance with some examples of the disclosure. As shown in FIG. 2A, the partial method starts with build-up of a package 200 (e.g., package 100) including a substrate 220 (e.g., substrate 120). The substrate 220 may comprise a core 230 (e.g., core 130), a first dielectric layer 240 (e.g., first dielectric layer 140) on a first side of the core 230, a second dielectric layer 250 (e.g., second dielectric layer 150) on a second side of the core 230 opposite the first dielectric layer 240, a plurality of pads 270 (e.g., plurality of pads 170) on the first dielectric layer 240, a plurality of traces 280 (e.g., plurality of traces 180) on the first dielectric layer 240, and a plurality of vias 223 (e.g., plurality of vias 123) extending between the first dielectric layer 240 and the second dielectric layer 250. The plurality of vias 223 may include a first via 224 proximate to a first edge 221 of the substrate 220 and a second via 225 proximate to a second edge 222 of the substrate 220. As shown in FIG. 2B, the partial method continues with adding a third dielectric layer 260 (e.g., third dielectric layer 160) on the first dielectric layer 240 such that each of the plurality of pads 270 and each of the plurality of traces 280 are encapsulated.

As shown in FIG. 2C, the partial method continues with a removal process such as mechanical grinding or etching to remove a portion of the third dielectric layer 260 such that surfaces of the first via 224, the second via 225, the plurality of pads 270, and the plurality of traces 280 are exposed. As shown in FIG. 2D, the partial method continues with the addition of a fourth layer 290 (e.g., fourth layer 190) on a portion of the third dielectric layer 260 such that the plurality of pads 270, and the plurality of traces 280, are exposed while only a bottom portion of the first via 224 and the second via 224 are exposed. As shown in FIG. 2E, the partial method concludes with a removal process to recess the tops of the plurality of pads 270 and the plurality of traces 280 along with the application of an organic solderability preservative material coating on the exposed and recessed pads 270 and traces 280.

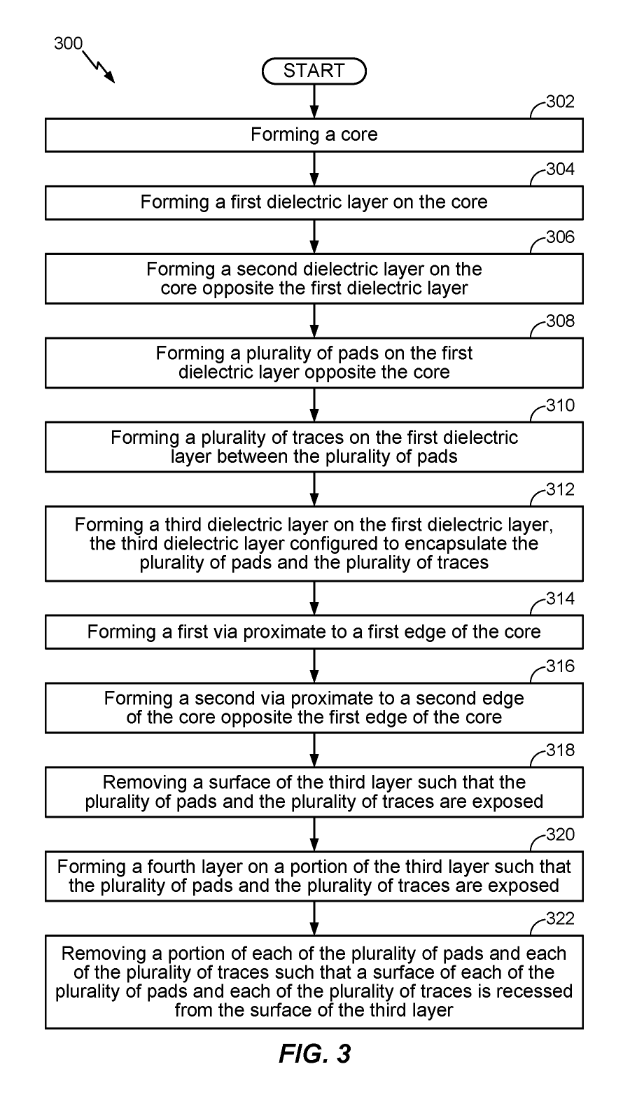

FIG. 3 illustrates an exemplary partial method 300 for forming a flip chip bump array (FCBGA) package in accordance with some examples of the disclosure. The partial method 300 begins in block 302 with forming a core (e.g., core 130 or core 230). The partial method 300 continues in block 304 with forming a first dielectric layer (e.g., first dielectric layer 140 or first dielectric layer 240) on the core. The partial method 300 continues in block 306 with forming a second dielectric layer (e.g., second dielectric layer 150 or second dielectric layer 250) on the core opposite the first dielectric layer. The partial method 300 continues in block 308 with forming a plurality of pads (e.g., plurality of pads 170 or plurality of pads 270) on the first dielectric layer opposite the core. The partial method 300 continues in block 310 with forming a plurality of traces (e.g., plurality of traces 180 or plurality of traces 280) on the first dielectric layer between the plurality of pads. The partial method 300 continues in block 312 with forming a third dielectric layer (e.g., third dielectric layer 160 or third dielectric layer 260) on the first dielectric layer, the third dielectric layer configured to encapsulate the plurality of pads and the plurality of traces. The partial method 300 continues in block 314 with forming a first via proximate to a first edge of the core. The partial method 300 continues in block 316 with forming a second via proximate to a second edge of the core opposite the first edge of the core. The partial method 300 continues in block 318 with removing a surface of the third dielectric layer such that the plurality of pads and the plurality of traces are exposed. The partial method 300 continues in block 320 with forming a fourth layer (e.g., fourth layer 190 or fourth layer 290) on a portion of the third dielectric layer such that the plurality of pads and the plurality of traces are exposed. The partial method 300 concludes in block 322 with removing a portion of each of the plurality of pads and each of the plurality of traces such that a surface of each of the plurality of pads and each of the plurality of traces is recessed from the surface of the third dielectric layer. Removing a portion of the pads and the traces may be done with mechanical grinding, soft etching, a combination of the two, or similar techniques as well as using an organic solderability preservative material coating on the exposed pads and traces. The various layers may be added by lamination or similar techniques. Removing a portion of the third dielectric layer may be done with mechanical grinding, etching, a combination of the two, or similar techniques.

The active side of a semiconductor or logic die is the part of the die that contains the active components of the die (e.g., transistors, resistors, capacitors, inductors etc.), which perform the operation or function of the die. The back side of the semiconductor die or logic die is the part that contains the active components of the die and is opposite from the active side. Pitch is the center-to-center distance between features of an integrated circuit such as interconnect lines or between a ball pad and a trace. Line and space terms refer to the width of an interconnect line, trace, or routing (the line or first dimension given) and the distance between adjacent interconnect lines, traces, or routings (the space or second dimension given). Substrates may comprise many different types of materials including, but not limited to, coreless, organic, silicon, silicon dioxide, aluminum oxide, sapphire, germanium, gallium arsenide, an alloy of silicon and germanium, or indium phosphide. Each trace may provide an escape line or routing out of the densely packed areas of an integrated circuit or semiconductor package such as between the pads of the bump array underneath the flip chip.

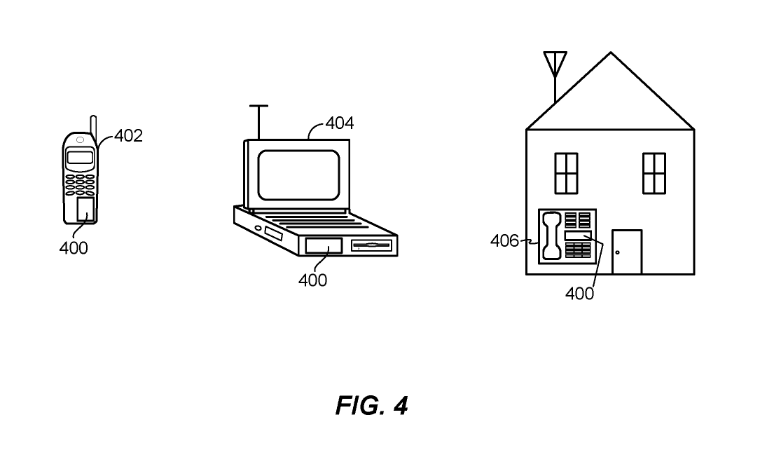

FIG. 4 illustrates various electronic devices that may be integrated with any of the aforementioned integrated device, semiconductor device, integrated circuit, die, interposer, package or package-on-package (PoP) in accordance with some examples of the disclosure. For example, a mobile phone device 402, a laptop computer device 404, and a fixed location terminal device 406 may include an integrated device 400 as described herein. The integrated device 400 may be, for example, any of the integrated circuits, dies, integrated devices, integrated device packages, integrated circuit devices, device packages, integrated circuit (IC) packages, package-on-package (PoP) devices described herein. The devices 402, 404, 406 illustrated in FIG. 4 are merely exemplary. Other electronic devices may also feature the integrated device 400 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

In this description, certain terminology is used to describe certain features. The term “mobile device” can describe, and is not limited to, a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). Further, the terms “user equipment” (UE), “mobile terminal,” “mobile device,” and “wireless device,” can be interchangeable.

It will be appreciated that various aspects disclosed herein can be described as functional equivalents to the structures, materials and/or devices described and/or recognized by those skilled in the art. For example, in one aspect, a package (e.g., package 100 or package 200) may comprise a substrate (e.g., substrate 120 or substrate 220) including a core (e.g., core 130 or core 230), a first dielectric layer (e.g., first dielectric layer 140 or first dielectric layer 240) on a first side of the core, a second dielectric layer (e.g., second dielectric layer 150 or second dielectric layer 250) on the first side of the core, and means for insulation (e.g., third dielectric layer 160 or third dielectric layer 260) on the first dielectric layer; means for connection (e.g., plurality of pads 170 or plurality of pads 270) embedded in the means for insulation such that a surface of each of the means for connection is below a surface of the means for insulation, the means for connection configured to connect to a flip chip semiconductor die (e.g., semiconductor die 110); means for routing (e.g., plurality of traces 180 or plurality of traces 280) embedded in the means for insulation such that a surface of each of the means for routing is below the surface of the means for insulation, at least two of the means for routing between each pair of adjoining means for connection; and a photo solder resist layer (e.g., fourth layer 190 or fourth layer 290) on a portion of the means for insulation.

It will be appreciated that the aforementioned aspects are merely provided as examples and the various aspects claimed are not limited to the specific references and/or illustrations cited as examples.

One or more of the components, processes, features, and/or functions illustrated in FIGS. 1, 2A-E, 3, and 4 may be rearranged and/or combined into a single component, process, feature or function or incorporated in several components, processes, or functions. Additional elements, components, processes, and/or functions may also be added without departing from the disclosure. It should also be noted that FIGS. 1, 2A-E, 3, and 4 and its corresponding description in the present disclosure is not limited to dies and/or ICs. In some implementations, FIGS. 1, 2A-E, 3, and 4 and its corresponding description may be used to manufacture, create, provide, and/or produce integrated devices. In some implementations, a device may include a die, an integrated device, a die package, an integrated circuit (IC), a device package, an integrated circuit (IC) package, a wafer, a semiconductor device, a package-on-package (PoP) device, and/or an interposer.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE) or other protocols that may be used in a wireless communications network or a data communications network.

The word “exemplary” is used herein to mean “serving as an example, instance, or illustration.” Any details described herein as “exemplary” is not to be construed as advantageous over other examples. Likewise, the term “examples” does not mean that all examples include the discussed feature, advantage or mode of operation. Furthermore, a particular feature and/or structure can be combined with one or more other features and/or structures. Moreover, at least a portion of the apparatus described hereby can be configured to perform at least a portion of a method described hereby.

The terminology used herein is for the purpose of describing particular examples and is not intended to be limiting of examples of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, actions, operations, elements, and/or components, but do not preclude the presence or addition of one or more other features, integers, actions, operations, elements, components, and/or groups thereof.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

Although some aspects have been described in connection with a device, it goes without saying that these aspects also constitute a description of the corresponding method, and so a block or a component of a device should also be understood as a corresponding method action or as a feature of a method action. Analogously thereto, aspects described in connection with or as a method action also constitute a description of a corresponding block or detail or feature of a corresponding device. Some or all of the method actions can be performed by a hardware apparatus (or using a hardware apparatus), such as, for example, a microprocessor, a programmable computer or an electronic circuit. In some examples, some or a plurality of the most important method actions can be performed by such an apparatus.

In the detailed description above it can be seen that different features are grouped together in examples. This manner of disclosure should not be understood as an intention that the claimed examples have more features than are explicitly mentioned in the respective claim. Rather, the situation is such that inventive content may reside in fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or a plurality of claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions of this method.

Furthermore, in some examples, an individual action can be subdivided into a plurality of sub-actions or contain a plurality of sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

1. A package comprising:
a substrate comprising a core, a first dielectric layer on a first side of the core, a second dielectric layer on a second side of the core opposite the first dielectric layer, and third dielectric layer on the first dielectric layer;
a plurality of pads embedded in the third dielectric layer such that a surface of each of the plurality of pads is below a surface of the third dielectric layer, the plurality of pads configured to connect to a flip chip semiconductor die and extend through the third dielectric layer;
a plurality of traces embedded in the third dielectric layer such that a surface of each of the plurality of traces is below the surface of the third dielectric layer and extends through the third dielectric layer, at least two of the plurality of traces between each pair of adjoining pads of the plurality of pads;
a first via proximate to a first edge of the substrate; and
a second via proximate to a second edge of the substrate opposite the first edge.

2. The package of claim 1, wherein the surface of each of the plurality of pads is approximately 0 to 4 μm flat depth below the surface of the third dielectric layer and the surface of each of the plurality of traces is approximately 0 to 4 μm flat depth below the surface of the third dielectric layer.

3. The package of claim 1, wherein the third dielectric layer is between approximately 10 to 20 μm in thickness.

4. The package of claim 1, wherein a distance between one of the plurality of pads and an adjoining one of the plurality of traces is between approximately 5 to 15 μm.

5. The package of claim 1, wherein a distance between one of the plurality of pads and an adjoining one of the plurality of traces is less than approximately 15 μm.

6. The package of claim 1, wherein a width of each of the plurality of traces is between approximately 3 to 15 μm.

7. The package of claim 1, wherein a width of each of the plurality of traces is less than approximately 15 μm.

8. The package of claim 1, wherein one to three of the plurality of traces are between each adjoining ones of the plurality of pads.

9. The package of claim 1, wherein the package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

10. A package comprising:
a substrate comprising a core, a first dielectric layer on a first side of the core, a second dielectric layer on a second side of the core opposite the first dielectric layer, and means for insulation on the first dielectric layer;
means for connection embedded in the means for insulation such that a surface of each of the means for connection is below a surface of the means for insulation, the means for connection configured to connect to a flip chip semiconductor die and extend through the means for insulation;
means for routing embedded in the means for insulation such that a surface of each of the means for routing is below the surface of the means for insulation and extends through the means for insulation, at least two of the means for routing between each pair of adjoining means for connection;
a first via proximate to a first edge of the substrate; and
a second via proximate to a second edge of the substrate opposite the first edge.

11. The package of claim 10, wherein the surface of each of the means for connection is approximately 0 to 4 μm flat depth below the surface of the means for insulation and the surface of each of the means for routing is approximately 0 to 4 μm flat depth below the surface of the means for insulation.

12. The package of claim 10, wherein the means for insulation is between approximately 10 to 20 μm in thickness.

13. The package of claim 10, wherein a distance between one of the means for connection and an adjoining one of the means for routing is between approximately 5 to 15 μm.

14. The package of claim 10, wherein a distance between one of the means for connection and an adjoining one of the means for routing is less than approximately 15 μm.

15. The package of claim 10, wherein a width of each of the means for routing is between approximately 3 to 15 μm.

16. The package of claim 10, wherein a width of each of the means for routing is less than approximately 15 μm.

17. The package of claim 10, wherein one to three of the means for routing are between each adjoining ones of the means for connection.

18. The package of claim 10, wherein the package is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

19. A method for forming a package substrate, comprising:
forming a core;
forming a first dielectric layer on the core;
forming a second dielectric layer on the core opposite the first dielectric layer;
forming a plurality of pads on the first dielectric layer opposite the core;
forming a plurality of traces on the first dielectric layer between the plurality of pads;
forming a third dielectric layer on the first dielectric layer, the third dielectric layer configured to encapsulate the plurality of pads and the plurality of traces;
forming a first via proximate to a first edge of the core;
forming a second via proximate to a second edge of the core opposite the first edge of the core;
removing a surface of the third dielectric layer such that the plurality of pads and the plurality of traces are exposed;
forming a fourth layer on a portion of the third dielectric layer such that the plurality of pads and the plurality of traces are exposed; and
removing a portion of each of the plurality of pads and each of the plurality of traces such that a surface of each of the plurality of pads and each of the plurality of traces is recessed from the surface of the third dielectric layer.

20. The method of claim 19, wherein the first via and the second via are configured to provide a connection from a first side of the core to a second side of the core opposite the first side.

21. The method of claim 19, wherein the third dielectric layer comprises one of ajinomoto-buildup film, prepreg insulation, resin coated copper, or photo-sensitive resistor material.

22. The method of claim 19, wherein the fourth layer comprises a photo solder resist material.

23. The method of claim 19, wherein the surface of each of the plurality of pads is approximately 0 to 4 μm flat depth below the surface of the third dielectric layer and the surface of each of the plurality of traces is approximately 0 to 4 μm flat depth below the surface of the third dielectric layer.

24. The method of claim 19, wherein the third dielectric layer is between approximately 10 to 20 μm in thickness.

25. The method of claim 19, wherein a distance between one of the plurality of pads and an adjoining one of the plurality of traces is between approximately 5 to 15 μm.

26. The method of claim 19, wherein a distance between one of the plurality of pads and an adjoining one of the plurality of traces is less than approximately 15 μm.

27. The method of claim 19, wherein a width of each of the plurality of traces is between approximately 3 to 15 μm.

28. The method of claim 19, wherein a width of each of the plurality of traces is less than approximately 15 μm.

29. The method of claim 19, wherein one to three of the plurality of traces are between each adjoining ones of the plurality of pads.

30. The method of claim 19, wherein the package substrate is incorporated into a device selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.
